(19) United States
(12) Patent Application Publication
(10) Pub. No.: US 2016/0336386 A1
(43) Pub. Date: Nov. 17, 2016

(54) THIN-FILM TRANSISTOR SUBSTRATE AND METHOD OF MANUFACTURING THE THIN-FILM TRANSISTOR SUBSTRATE

(71) Applicant: JOLED INC., Tokyo (JP)

(72) Inventor: Toru SAITO, Tokyo (JP)

(73) Assignee: JOLED INC., Tokyo (JP)

(21) Appl. No.: 15/102,320

(22) PCT Filed: Aug. 20, 2014
(86) PCT No.: PCT/JP2014/004243

§ 371 Date: Jun. 7, 2016

(30) Foreign Application Priority Data
Dec. 10, 2013 (JP) 2013-255510

(51) Int. Cl. H01L 27/32; H01L 27/12; H01L 23/532

(52) U.S. Cl. CPC H01L 27/3279; H01L 23/53228; H01L 27/1225; H01L 27/3248; H01L 27/3246

(57) ABSTRACT

A TFT substrate has a thin-film transistor including an oxide semiconductor layer, a source electrode, and a drain electrode, and includes: a first wiring line formed in a positionally-higher layer than that of the source electrode and the drain electrode, and connected to at least the source electrode or the drain electrode; and a terminal formed in a higher layer than that of the first wiring line, and connected to the first wiring line. The source electrode or the drain electrode connected to the first wiring line contains copper. The first wiring line is a multilayer film having a first film (transparent conductive film), a second film (copper film), and a third film (copper-manganese alloy film) laminated in this order from the bottom. The terminal comprises an aluminum alloy.

### TECHNICAL FIELD

The present disclosure relates to a thin-film transistor substrate and a method of manufacturing the thin-film transistor substrate.

### BACKGROUND ART

Thin-film transistor (TFT) substrates having TFTs formed thereon as switching elements or drive elements are used in active matrix display apparatuses, such as liquid crystal display apparatuses and organic electroluminescent (EL) display apparatuses. For example, Patent Literature (PTL) 1 discloses an active matrix organic EL display apparatus including a TFT substrate.

Structure examples of a TFT includes the following: a bottom-gate TFT structure in which a gate electrode is formed below a channel layer (i.e., the substrate side); and a top-gate TFT structure in which a gate electrode is formed above a channel layer. As an example, a silicon semiconductor or an oxide semiconductor is used as a channel layer of a TFT.

On a TFT substrate having a plurality of pixels arranged in a matrix, a plurality of wiring lines are formed to transmit signals (voltages) to drive the pixels.

### CITATION LIST

### Patent Literature

[PTL 1] Japanese Unexamined Patent Application Publication No. 2010-27584

### SUMMARY OF INVENTION

### Technical Problem

In recent years, upsizing of substrates due to large screens of display apparatuses has caused the wiring lines on the TFT substrate to be longer, thereby increasing the wiring resistance. Thus, a lower wiring resistance is desired.

The wiring lines are made using the same material as a source electrode and a drain electrode, and formed in the same layer as the source electrode and the drain electrode. On this account, the source electrode and the drain electrode are required to perform not only as the TFTs but also as the wiring lines.

With this being the situation, it has been proposed that copper (Cu), which is of low resistance, is used as the material for the source electrode and the drain electrode.

However, the conventional technique cannot provide a TFT substrate achieving desired performance.

The present disclosure has an object to provide a TFT substrate achieving desired performance.

### Solution to Problem

To achieve the stated object, a thin-film transistor substrate according to an aspect has a thin-film transistor including an oxide semiconductor layer, a source electrode, and a drain electrode, and includes: a first wiring line that is formed in a layer positionally higher than a layer in which the source electrode and the drain electrode are formed, and is connected to at least one of the source electrode and the drain electrode; and a terminal that is formed in a layer positionally higher than the layer in which the first wiring line is formed, and is connected to the first wiring line, wherein the at least one of the source electrode and the drain electrode that is connected to the first wiring line contains copper, the first wiring line is a multilayer film in which a transparent conductive film, a copper film, and a copper-manganese alloy film are laminated in stated order from the bottom, and the terminal comprises an aluminum alloy.

A method of manufacturing a thin-film transistor substrate includes: forming an oxide semiconductor layer; forming a source electrode and a drain electrode that are connected to the oxide semiconductor layer; forming a first wiring line in a layer positionally higher than a layer in which the source electrode and the drain electrode are formed, the first wiring line being connected to at least one of the source electrode and the drain electrode; and forming a terminal in a layer positionally higher than the layer in which the first wiring line is formed, the terminal being connected to the first wiring line, wherein the at least one of the source electrode and the drain electrode that is connected to the first wiring line contains copper, the terminal comprises an aluminum alloy, and the forming of a first wiring line includes forming a transparent conductive film, forming a copper film on the transparent conductive film, and forming a copper-manganese alloy film on the copper film.

### Advantageous Effects of Invention

The present disclosure can provide a TFT substrate achieving desired performance.

### BRIEF DESCRIPTION OF DRAWINGS

FIG. 1 is a partially-cutaway perspective view of an organic EL display apparatus according to Embodiment.

FIG. 2 is a perspective view showing an example of a pixel bank of the organic EL display apparatus according to Embodiment.

FIG. 3 is an electric circuit diagram showing a configuration of a pixel circuit included in the organic EL display apparatus according to Embodiment.

FIG. 4 is a schematic cross-sectional view of a TFT substrate according to Embodiment.

FIG. 5 is an enlarged plan view showing a surrounding structure of a slit part in a terminal section of the TFT substrate according to Embodiment.

FIG. 6A is a cross-sectional view showing a process of forming a gate electrode in a method of manufacturing a TFT substrate according to Embodiment.

FIG. 6B is a cross-sectional view showing a process of forming a gate insulating film in the method of manufacturing a TFT substrate according to Embodiment.

FIG. 6C is a cross-sectional view showing a process of forming an oxide semiconductor layer in the method of manufacturing a TFT substrate according to Embodiment.

FIG. 6D is a cross-sectional view showing a process of forming a first insulating layer in the method of manufacturing a TFT substrate according to Embodiment.

FIG. 6E is a cross-sectional view showing a process of forming contact holes in the first insulating layer in the method of manufacturing a TFT substrate according to Embodiment.

FIG. 6F is a cross-sectional view showing a process of forming a source electrode and a drain electrode in the method of manufacturing a TFT substrate according to Embodiment,

FIG. 6G is a cross-sectional view showing a process of forming a second insulating layer in the method of manufacturing a TFT substrate according to Embodiment.

FIG. 6H is a cross-sectional view showing a process of forming contact holes in the second insulating layer in the method of manufacturing a TFT substrate according to Embodiment.

FIG. 6I is a cross-sectional view showing a process of forming a multilayer film in the method of manufacturing a TFT substrate according to Embodiment.

FIG. 6J is a cross-sectional view showing a first patterning process performed on the multilayer film in the method of manufacturing a TFT substrate according to Embodiment.

FIG. 6K is a cross-sectional view showing a second patterning process performed on the multilayer film in the method of manufacturing a TFT substrate according to Embodiment.

FIG. 6L is a cross-sectional view showing a process of forming a third insulating layer in the method of manufacturing a TFT substrate according to Embodiment.

FIG. 6M is a cross-sectional view showing a process of forming an anode and a terminal in the method of manufacturing a TFT substrate according to Embodiment.

FIG. 7 is a schematic cross-sectional view of a TFT substrate according to a comparative example.

FIG. 8 is a plan view showing that a terminal section of the TFT substrate shown in FIG. 7 is etched.

FIG. 9A is a cross-sectional scanning electron microscope (SEM) image of a region A enclosed by a broken line shown in FIG. 7.

FIG. 9B is a diagram showing the number of contact defects occurring between the electrode and the drain electrode in the TFT substrate shown in FIG. 7.

FIG. 10A is a cross-sectional SEM image of a region A enclosed by a broken line shown in FIG. 4.

FIG. 10B is a diagram showing the number of contact defects occurring between the electrode and the drain electrode in the TFT substrate shown in FIG. 4.

### DESCRIPTION OF EMBODIMENTS

Hereinafter, exemplary embodiments according to the present disclosure are described with reference to the accompanying drawings. It should be noted that each of the exemplary embodiments below describes only a preferred specific example. Therefore, the numerical values, shapes, materials, structural elements, the arrangement and connection of the structural elements, processes (steps), the processing order of the steps, and so forth described in the following exemplary embodiments are merely examples, and are not intended to limit the present invention. Thus, among the structural elements in the following exemplary embodiments, structural elements that are not recited in any one of the independent claims indicating top concepts according to the present invention are described as arbitrary structural elements.

Note that all the drawings are only schematic diagrams and are not necessarily precise representations. Note also that, in all the drawings, the same reference numerals are given to the substantially same structural elements and redundant description thereof shall be omitted or simplified.

### Embodiment

A configuration of an organic EL display apparatus is first described as an example of a display apparatus including a TFT substrate.

### [Organic EL Display Apparatus]

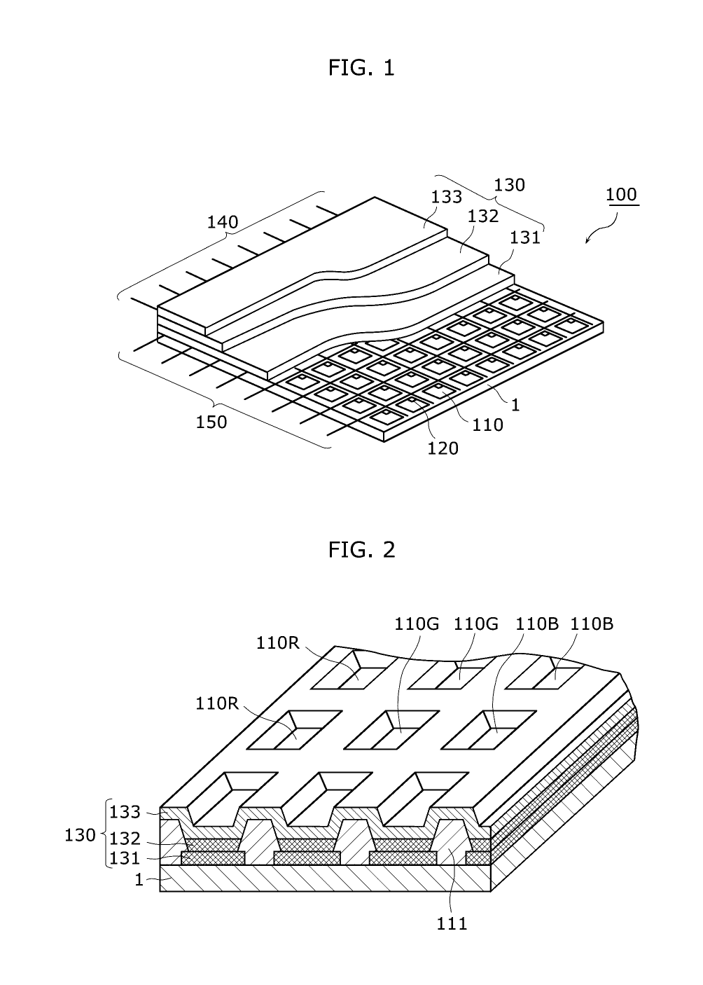

FIG. 1 is a partially-cutaway perspective view of the organic EL display apparatus according to Embodiment. FIG. 2 is a perspective view showing an example of a pixel bank of the organic EL display apparatus according to Embodiment.

As shown in FIG. 1, an organic EL display apparatus 100 is formed by laminating the following: a TFT substrate (a TFT array substrate) 1 on which a plurality of thin-film transistors are arranged; and an organic EL element (a light emitting unit) 130 having an anode 131 as a lower electrode, an EL layer 132 as a light emitting layer comprising an organic material, and a cathode 133 as a transparent upper electrode.

In Embodiment, the organic EL display apparatus 100 is of top-emission type, and the anode 131 is a repeller electrode. The organic EL display apparatus 100 is not limited to be of top-emission type, and may be of bottom-emission type.

A plurality of pixels 110 are arranged in a matrix on the TFT substrate 1. Each of the pixels 110 is provided with a pixel circuit 120.

The organic EL element 130 is formed for each of the pixels 110. The light emission of the organic EL element 130 is controlled by the pixel circuit 120 of the corresponding pixel 110. The organic EL element 130 is formed on an interlayer insulating film (a flattening film) formed in a manner that the thin-film transistors are covered.

Moreover, the organic EL element 130 has a configuration in which the EL layer 132 is interposed between the anode 131 and the cathode 133. Furthermore, a hole transport layer is laminated between the anode 131 and the EL layer 132, and an electron transport layer is laminated between the EL layer 132 and the cathode 133. It should be noted that an additional organic function layer may be interposed between the anode 131 and the cathode 133

Drive of each of the pixels 110 is controlled by the corresponding pixel circuit 120. On the TFT substrate 1, the following are formed: a plurality of gate lines (scanning lines) 140 arranged along the direction of rows of the pixels 110; a plurality of source lines (signal lines) 150 arranged along the direction of columns of the pixels 110 to cross the gate lines 140; and a plurality of power source lines (not illustrated in FIG. 1) arranged in parallel with the source lines 150. The pixels 110 are partitioned by, for example, the gate lines 140 and the source lines 150 that are orthogonal to each other.

The gate line 140 is connected to, for each of the rows, the gate electrode of the thin-film transistor operating as a switching element included in the pixel circuit 120. The source line 150 is connected to, for each of the columns, the source electrode of the thin-film transistor operating as a switching element included in the pixel circuit 120. The power source line is connected to, for each of the columns, the drain electrode of the thin-film transistor operating as a drive element included in the pixel circuit 120.

As shown in FIG. 2, each of the pixels 110 of the organic EL display apparatus 100 includes subpixels 110R, 110G, and 110B corresponding to three colors (red, green, and blue). A plurality of sets of these subpixels 110R, 110G, and 110B are arranged in a matrix on a display surface. The subpixels 110R, 110G, and 110B are separated from each other by a bank 111. The bank 111 is formed in a grid in a manner that elongated protrusions extending in parallel with the gate lines 140 crosses with elongated protrusions extending in parallel with the source lines 150. Parts surrounded by the protrusions (that is, opening parts of the bank 111) correspond to the subpixels 110R, 110G, and 110B on a one-to-one basis. Although the bank 111 is a pixel bank in Embodiment, the bank 111 may be a line bank.

The anode 131 is formed for each of the subpixels 110R, 110G, and 110B, on the interlayer insulating film (the flattening film) on the TFT substrate 1 and in the opening part of the bank 111. Similarly, the EL layer 132 is formed for each of the subpixels 110R, 110G, and 110B, on the anode 131 and in the opening part of the bank 111. The cathode 133, which is transparent, is formed continuously on the banks 111 to cover all the EL layers 132 (that is, all the subpixels 110R, 110G, and 110B).

Moreover, the pixel circuit 120 is provided for each of the subpixels 110R, 110G, and 110B. Each of the subpixels 110R, 110G, and 110B is electrically connected to the corresponding pixel circuit 120 via a contact hole and a relay electrode. Note that the configurations of the subpixels 110R, 110G, and 110B are identical except that the colors emitted from the respective EL layers 132 are different.

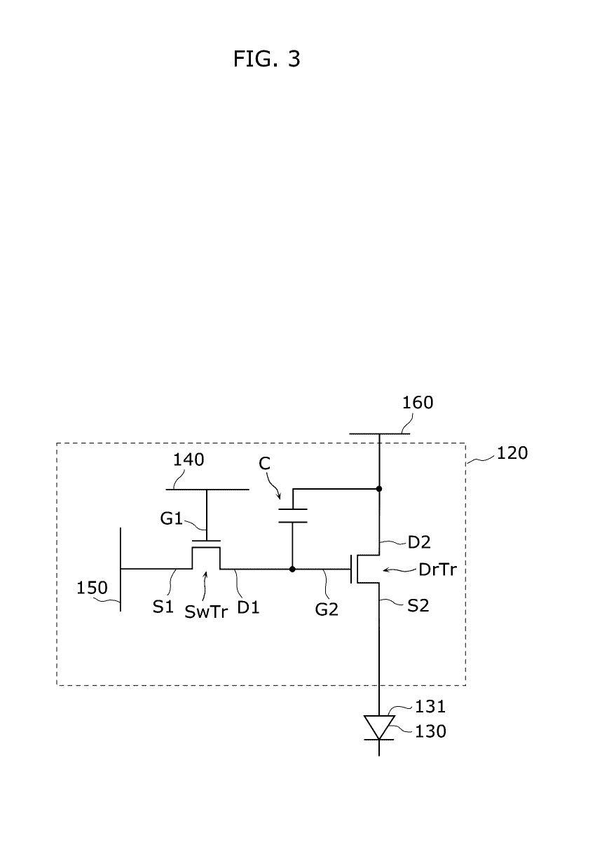

Here, a circuit configuration of the pixel circuit 120 included in the pixel 110 is described with reference to FIG. 3. FIG. 3 is an electric circuit diagram showing a configuration of the pixel circuit included in the organic EL display apparatus according to Embodiment.

As shown in FIG. 3, the pixel circuit 120 includes a thin-film transistor SwTr operating as a switching element, a thin-film transistor DrTr operating as a drive element, and a capacitor C storing data used for displaying on the corresponding pixel 110. In Embodiment, the thin-film transistor SwTr is a switching transistor for selecting the pixel 110, and the thin-film transistor DrTr is a drive transistor for driving the organic EL element 130.

The thin-film transistor SwTr includes the following: a gate electrode G1 connected to the gate line 140; a source electrode S1 connected to the source line 150; a drain electrode D1 connected to the capacitor C and a gate electrode G2 of the thin-film transistor DrTr; and a semiconductor film (not illustrated). When a predetermined voltage is applied to the gate line 140 and the source line 150 both connected to the thin-film transistor SwTr, the voltage applied to the source line 150 is stored as data voltage into the capacitor C.

The thin-film transistor DrTr includes the following: the gate electrode G2 connected to the drain electrode D1 of the thin-film transistor SwTr and to the capacitor C; a drain electrode D2 connected to a power source line 160 and the capacitor C; a source electrode S2 connected to the anode 131 of the organic EL element 130; and a semiconductor film (not illustrated). The thin-film transistor DrTr supplies a current corresponding to the data voltage held by the capacitor C from the power source line 160 to the anode 131 of the organic EL element 130, via the source electrode S2. This enables the organic EL element 130 to have a drive current flowing from the anode 131 to the cathode 133, thereby allowing the EL layer 132 to emit light.

It should be noted that the organic EL display apparatus 100 having the aforementioned configuration adopts the active matrix scheme by which display control is performed for each of the pixels 110 located at intersection points of the gate lines 140 and the source lines 150. With this, the thin-film transistors SwTr and DrTr of the individual pixel 110 (each of the subpixels 110R, 110G, and 110B) selectively cause the corresponding organic EL element 130 to emit light. As a result, a desired image is displayed.

### [Thin-Film Transistor Substrate]

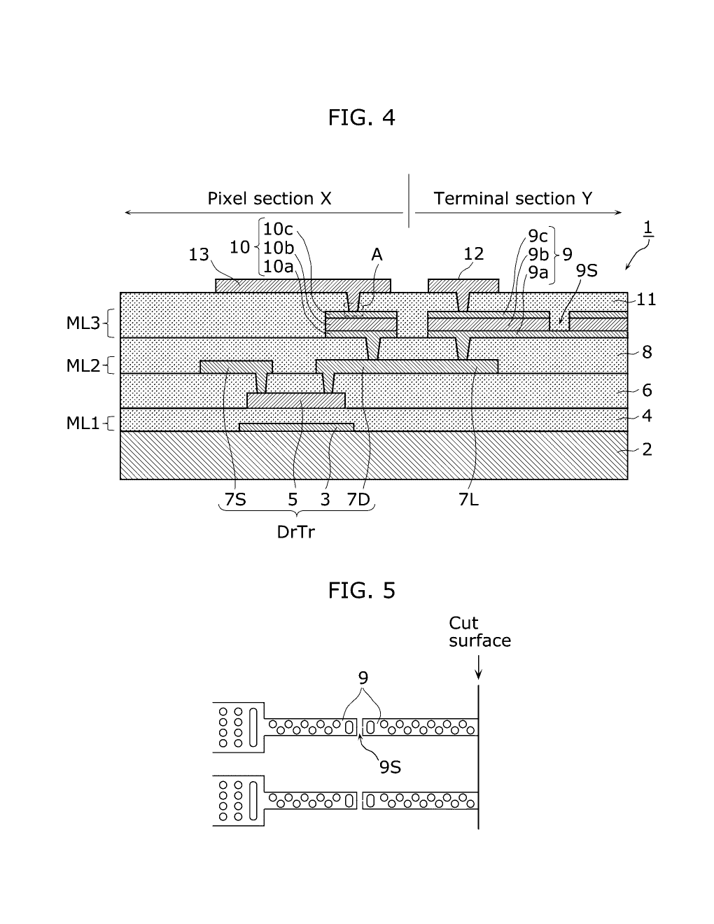

The following describes the TFT substrate according to Embodiment. FIG. 4 is a schematic cross-sectional view of the TFT substrate according to Embodiment. The TFT substrate 1 included in the organic EL display apparatus 100 described above is described in Embodiment below. Although the thin-film transistor DrTr is described, the thin-film transistor SwTr has the same configuration as the thin-film transistor DrTr. To be more specific, the thin-film transistor described below can be applied to both the switching transistor and the drive transistor.

As shown in FIG. 4, the thin-film transistor DrTr is formed in the TFT substrate 1. The TFT substrate 1 includes a substrate 2, a gate electrode 3, a gate insulating film 4, an oxide semiconductor layer 5, an insulating layer 6, a source electrode 7S, a drain electrode 7D, an extension line 7L, an insulating layer 8, a first wiring line 9, a second wiring line 10 (each of the first wiring line 9 and the second wiring line 10 is an upper-layer wiring line), an insulating layer 11, a terminal 12, and an electrode 13.

Each of the first wiring line 9 and the second wiring line 10 is a multilayer film, and is formed in a layer positionally higher than a layer in which the source electrode 7S and the drain electrode 7D are formed. The second wiring line 10 is formed in the layer in which the first wiring line 9 is formed. More specifically, the first wiring line 9 and the second wiring line 10 are formed in the same layer.

The terminal 12 and the electrode 13 are formed in a layer positionally higher than the layer in which the first wiring line 9 and the second line are formed. The electrode 13 is formed in the layer in which the terminal 12 is formed. More specifically, the terminal 12 and the electrode 13 are formed in the same layer.

Each of the gate electrode 3, the source electrode 7S, the drain electrode 7D, the first wiring line 9, the second wiring line 10, the terminal 12, and the electrode 13 comprises a metal material. Each of the layers in which these electrodes, lines, and terminal are formed is a metal layer (a wiring layer). To be more specific, the layer in which the gate electrode 3 is formed is a first metal layer (a first layer) ML1. The layer in which the source electrode 7S and the drain electrode 7D are formed is a second metal layer (a second layer) ML2, which is one layer above the first metal layer ML1. The layer in which the first wiring line 9 and the second wiring line 10 are formed is a third metal layer (a third layer) ML3, which is one layer above the second metal layer ML2.

Each of the first metal layer ML1, the second metal layer ML2, and the third metal layer ML3 can be used as a wiring layer for various kinds of lines. To be more specific, patterning a metal film (a conductive film) formed on the corresponding metal layer into a predetermined shape allows a desired wiring line to be formed in the predetermined shape in addition to the aforementioned electrodes, lines, and terminal. The gate lines 140 and the source lines 150 shown in FIG. 1 and the power source lines 160, for example, are formed in the metal layers. Moreover, contact holes are formed in an insulating layer interposed between the upper and lower metal layers to enable the lines in the metal layers to be connected to each other and the lines and the electrodes to be connected to each other.

As shown in FIG. 4, the thin-film transistor DrTr in the TFT substrate 1 includes the gate electrode 3, the gate insulating film 4, the oxide semiconductor layer 5, the insulating layer 6, the source electrode 7S, and the drain electrode 7D. The gate electrode 3, the source electrode 7S, and the drain electrode 7D correspond to the gate electrode G2, the source electrode S2, and the drain electrode D2, respectively, shown in FIG. 3. The thin-film transistor DrTr according to Embodiment is a bottom-gate TFT.

As shown in FIG. 4, the TFT substrate 1 has a pixel section (a pixel region) X and a terminal section (a terminal region) Y. The pixel section X is a region in which the pixels 110 shown in FIG. 1 are formed, and corresponds to a display region of the organic EL display apparatus. The terminal section Y is a region located outside the pixel section X, and is used as an extraction region (a draw-out region) for extracting the line formed in the pixel section and connecting the extracted line to, for example, an external line. In the terminal section Y, the extracted line is connected to, for example, a chip-on-film (COF) having wiring lines by thermocompression bonding and then electrically connected to, for example, an external circuit substrate.

Next, each of the structural elements included in the TFT substrate 1 is described in detail, with reference to FIG. 4.

The substrate 2 is a glass substrate, for example. When the thin-film transistor DrTr is used for a flexible display, a flexible substrate, such as a resin substrate, may be used as the substrate 2. Note that an undercoating layer may be formed on a surface of the substrate 2.

The gate electrode 3 is formed in a predetermined shape above the substrate 2. The gate electrode 3 comprises the following, for example: a metal, such as titanium (Ti), molybdenum (Mo), tungsten (W), aluminum (Al), gold (Au), or copper (Cu); or a conductive oxide, such as an indium tin oxide (ITO). Examples of the metal used as the gate electrode 3 further include an alloy, such as molybdenum tungsten (MoW). To enhance the film adhesion, a multilayer product including metals, such as Ti, Al, and Au, which have excellent adhesion to oxides may be used as the gate electrode 3.

The gate insulating film 4 is interposed between the gate electrode 3 and the oxide semiconductor layer 5. The gate insulating film 4 is formed on the substrate 2 to cover the gate electrode 3. For example, the gate insulating film 4 is a single-layer film comprising one of, or a multilayer film comprising, an oxide thin film such as a silicon oxide film or a hafnium oxide film, a nitride film such as a silicon nitride film, and a silicon oxynitride film.

The oxide semiconductor layer 5 is formed in a predetermined shape above the substrate 2. The oxide semiconductor layer 5 is a channel layer (a semiconductor layer) of the thin-film transistor DrTr and is formed opposite to the gate electrode 3. As an example, the oxide semiconductor layer 5 is formed on the gate insulating film 4 and above the gate electrode 3, in the shape of an island.

It is preferable that the oxide semiconductor layer 5 comprises a transparent amorphous oxide semiconductor (TAOS), such as amorphous indium gallium zinc oxide (InGaZnOx:IGZO) containing In—Ga—Zn—O. The ratio among In, Ga, and Zn may be about 1:1:1, for example. Moreover, the range of the ratio among In, Ga, and Zn may be, but not limited to, 0.8 to 1.2:0.8 to 1.2:0.8 to 1.2. The thin-film transistor having the channel layer comprising the transparent amorphous oxide semiconductor has a high carrier mobility and is thus suitable for a large-screen or high-resolution display apparatus. Furthermore, the transparent amorphous oxide semiconductor, which enables low-temperature film formation, can be easily formed on a flexible substrate comprising, for example, plastic or film.

As an example, the amorphous oxide semiconductor comprising InGaZnOx can be formed by a vapor-phase film formation method, such as a sputtering method or a laser evaporation method, which targets a polycrystalline sintered body having the composition of InGaO₃(ZnO)₄.

The insulating layer 6 (a first insulating layer) is formed on the gate insulating film 4 to cover the oxide semiconductor layer 5. To be more specific, the oxide semiconductor layer 5 is covered with the insulating layer 6, which thus functions as a protection layer (a channel protection layer) for protecting the oxide semiconductor layer 5. As an example, the insulating layer 6 is a silicon oxide film (SiO₂). A part of the insulating layer 6 has a through opening. The oxide semiconductor layer 5 is connected to the source electrode 7S and the drain electrode 7D via this opening part (the contact holes) of the insulating layer 6.

The source electrode 7S and the drain electrode 7D are formed in predetermined shapes on the insulating film 6. To be more specific, the source electrode 7S and the drain electrode 7D are connected to the oxide semiconductor layer 5 via the contact holes formed in the insulating layer 6, and disposed opposite to each other at a predetermined spacing on the insulating layer 6 in the horizontal direction of the substrate.

The source electrode 7S or the drain electrode 7D that is connected to at least the first wiring line 9 contains copper (Cu). In Embodiment, each of the source electrode 7S and the drain electrode 7D contains Cu as a major component. To be more specific, each of the source electrode 7S and the drain electrode 7D is a Cu film (a copper film) comprising pure Cu.

In this way, the source electrode 7S and the drain electrode 7D contain Cu, which is a low-resistance material. This allows the source electrode 7S and the drain electrode 7D to have low resistance, and also allows the wiring lines (which are formed in the layer in which the source electrode 7S and the drain electrode 7D are formed) formed in the second metal layer to be low-resistance lines.

In the example shown in FIG. 4, the extension line 7L is formed by extending the drain electrode 7D. The extension line 7L is used for drawing out the drain electrode 7D formed in the pixel section X to the terminal section Y, and connects the drain electrode 7D to the first wiring line 9.

Note that each of the source electrode 7S and the drain electrode 7D may be a multilayer film instead of a single-layer film. Examples of such a multilayer film may include the following: a two-layer film in which a Cu film and a copper-manganese alloy film (a CuMn alloy film) are laminated in this order from the bottom; a three-layer film in which a CuMn alloy film, a Cu film, and a CuMn alloy film are laminated in this order from the bottom; and a three-layer film in which a Mo film, a Cu film, and a CuMn alloy film are laminated in this order from the bottom.

The use of the CuMn alloy film as a top layer (a cap layer) for each of the source electrode 7S and the drain electrode 7D can reduce the degradation of the Cu film that may be caused by the oxidation of Cu atoms. Thus, an increase in resistivity of the first wiring line 9 and the second wiring line 10 that may be caused by the Cu oxidation can also be suppressed. Moreover, the use of the CuMn film or the Mo film as a bottom layer for each of the source electrode 7S and the drain electrode 7D can reduce the diffusion of the Cu atoms to a lower layer and also enhance the adhesion to an underlayer. It should be noted that the CuMn alloy film in Embodiment refers to a film comprising an alloy of copper and manganese.

The insulating layer 8 (a second insulating layer) is formed on the insulating layer 6 to cover the source electrode 7S and the drain electrode 7D. The insulating layer 8 functions as a protection layer for protecting the source electrode 7S and the drain electrode 7D. Furthermore, the insulating layer 8 is an interlayer insulating film interposed between the second metal layer ML2 and the third metal layer ML3. The insulating layer 8 may be a single-layer film comprising one of, or a multilayer film comprising, oxide films such as a silicon oxide film (SiO₂) and an aluminum oxide film (Al₂O₃).

Moreover, a part of the insulating layer 8 has a through opening. Via this opening part (the contact holes), the drain electrode 7D is connected to the first wiring line 9, and the source electrode 7S is connected to the second line.

The first wiring line 9 is formed in a predetermined shape on the insulating layer 8. The first wiring line 9 is connected to at least one of the source electrode 7S and the drain electrode 7D. In Embodiment, the first wiring line 9 is connected to the drain electrode 7D via the contact hole formed in the insulating layer 8. Furthermore, the first wiring line 9 is also connected to the terminal 12 via a contact hole formed in the insulating layer 11.

The first wiring line 9 is a multilayer film in which the following are laminated from bottom to top in the order as follows: a first film 9a that is a transparent conductive film; a second film 9b that is a copper film (a Cu film); and a third film 9c that is a copper-manganese alloy film (a CuMn alloy film). In Embodiment, the first film 9a, which is a transparent conductive film, is an indium tin oxide film (an ITO film). It is desirable that the second film 9b, which is a Cu film, is thicker than the first film 9a and the third film 9c.

As shown in FIG. 4 and FIG. 5, the first wiring line 9 according to Embodiment includes a slit part 9S. FIG. 5 is an enlarged plan view showing a surrounding structure of the slit part 9S in the terminal section Y of the TFT substrate shown in FIG. 4.

As shown in FIG. 5, the slit part 9S refers to a part cut in a slit in the first wiring line 9. The slit part 9S corresponds to slits formed in the two films, which are the second film 9b (the Cu film) and the third film 9c (the CuMn alloy film) among the first film 9a (the ITO film), the second film 9b, and the third film 9c of the first wiring line 9. In other words, only the first film 9a (the ITO film) of the first wiring line 9 is present in the slit part 9S. The slit width of the slit part 9S may be about 10 μm or 20 μm, for example.

The slit part 9S formed in the first wiring line 9 in this way can stop, at the slit part 9S itself, the copper corrosion propagating from the cut surface of the TFT substrate 1. More specifically, since the second film 9b, which is the Cu film, is cut in the slit part 9S, the Cu corrosion can be stopped at the slit part 9S.

In FIG. 4, the first wiring line 9 is a drain line terminal connected to the drain electrode 9D, and the slit part 9S is connected to this drain line terminal. However, the slit part 9S may be formed in a gate line terminal (not illustrated) or a source line terminal (not illustrated),

The second wiring line 10 is formed in a predetermined shape on the insulating layer 8. The second wiring line 10 is connected to the electrode 13 via the contact hole formed in the insulating layer 11. Furthermore, the second wiring line 10 is also connected to the drain electrode 7D via the contact hole formed in the insulating layer 8.

The second wiring line 10 is formed in the layer (the third metal layer MU) in which the first wiring line 9 is also formed, and is a multilayer film having the same structure as the first wiring line 9. To be more specific, the second wiring line 10 is a multilayer film in which the following are laminated from bottom to top in the order as follows: a first film 10a that is a transparent conductive film; a second film 10b that is a Cu film; and a third film 10c that is a CuMn alloy film. The first film 10a of the second wiring line 10, which is a transparent conductive film, is also an ITO film.

The use of the Cu films in the first wiring line 9 and the second wiring line 10 in this way allows the first wiring line 9 and the second wiring line 10 to be low-resistance lines.

Moreover, the use of the CuMn alloy film as the top layer (the cap layer) for each of the first wiring line 9 and the second wiring line 10 can reduce the degradation of the Cu film that may be caused by the oxidation of Cu atoms. Thus, an increase in resistivity of the first wiring line 9 and the second wiring line 10 that may be caused by the Cu oxidation can also be suppressed.

Moreover, the use of the transparent conductive film (the ITO film) as the bottom layer for each of the first wiring line 9 and the second wiring line 10 enables the first wiring line 9 to function as a continuous line without being cut in the slit part 9S even though the slit part 9S is formed in the first wiring line 9.

Each of the ITO films, which are the first film 9a in the first wiring line 9 and the first film 10a in the second wiring line 10, may be 50 nm for example. Each of the Cu films, which are the second films 9b and 10b, may be 300 nm for example. Each of the CuMn alloy films, which are the third films 9c and 10c, may be 50 nm to 60 nm for example. Although the ITO film is used as the transparent conductive film for each of the first film 9a and the second film 10a, a different transparent conductive oxide may be used.

Here, the resistivity of the CuMn alloy film used as the third films 9c and 10c was measured with variation in the Mn concentration. With the Mn concentration of 0% and 4%, the resistivity rapidly increases after a heating temperature exceeds 250° C. On the other hand, with the Mn concentration of 8% and 10%, no fluctuations were observed in the resistivity at heating temperatures of 300° C. or lower. Typically speaking, after various lines are formed on the TFT substrate, a heat resistance of 300° C. is required in accordance with an upper limit of a subsequent process temperature. On this account, the Mn concentration of 8% or higher for the CuMn alloy film can provide the heat resistance to withstand the upper limit of the process temperature. More specifically, it is preferable that the Mn concentration of the CuMn alloy film used as the third films 9c and 10c is 8% or higher. It should be noted that an upper limit of the Mn concentration of the CuMn alloy film is practically 15%. Note also that the same can be said about the Mn concentrations of the CuMn alloy films of the source electrode 7S and the drain electrode 7D.

The insulating layer 11 (a third insulating layer) is formed on the insulating layer 8 in a manner that the first wiring line 9 and the second wiring line 10 are covered. In addition to being a protection layer for protecting the first wiring line 9 and the second wiring line 10, the insulating layer 11 also functions as a flattening layer for flattening the first wiring line 9 and the second wiring line 10. On account of this, the insulating layer 11 having the thickness of 4 μm is formed in Embodiment.

For example, an acrylic resin can be used for the insulating layer 11. To be more specific, a resin-coated photosensitive insulating material is used which contains silsesquioxane, acrylic, and siloxane and can attenuate light of wavelength of 450 nm or less. The insulating layer 11 may be a multilayer film comprising this photosensitive insulating material and an inorganic insulating material or a single-layer film comprising an organic insulating material. Examples of the organic insulating material include an oxide silicon, an aluminum oxide, and a titanium oxide. A film comprising the organic insulating material is formed by, for example, a chemical vaper deposition (CVD) method, a sputtering method, or an atomic layer deposition (ALD) method.

Moreover, a part of the insulating layer 11 has a through opening. Via this opening part (the contact holes), the first wiring line 9 is connected to the terminal 12, and the second wiring line 10 is connected to the electrode 13.

The terminal 12 is formed in a predetermined shape on the insulating layer 11 in the terminal section Y of the TFT substrate 1. The terminal 12 is an external connection terminal to be connected to an external component, such as a COF, and is an extraction electrode for extracting the lines formed in the pixel section X directly or indirectly to the terminal section Y. The material used for the terminal 12 is the same as the material used for the electrode 13, and is an Al alloy film comprising a predetermined aluminum alloy (Al alloy) as described later.

In Embodiment, the terminal 12 is connected to the first wiring line 9 via the contact hole formed in the insulating layer 11. With this, the terminal 12 is electrically connected to, via the first wiring line 9, the line extended from the drain electrode 7D of the pixel section X.

The electrode 13 is formed in a predetermined shape on the insulating layer 11 in the pixel section X of the TFT substrate 1. The electrode 13 is formed in the layer (a fourth metal layer ML4) in which the terminal 12 is formed. Thus, the material used for the electrode 13 is the same as the material used for the terminal 12.

The electrode 13 is an Al alloy film comprising an aluminum alloy (Al alloy). The Al alloy used for the electrode 13 and the terminal 12 may be, for example, an Al-Ag alloy or an Al-Ni alloy. As an example of the Al-Ag alloy, an Al alloy containing 1 to 6 atomic percent of Ag may be used. As an example of the Al-Ni alloy, an Al alloy containing 0.1 to 2 atomic percent of Ni may be used. The Al alloy film can be formed by the sputtering method or a vacuum vapor deposition method. The thickness of the electrode 13 is 400 nm for example.

In Embodiment, the electrode 13 is a pixel electrode. To be more specific, the electrode 13 corresponds to the anode 131 of the organic EL element 130 shown in FIG. 1 and is a repeller electrode.

### [Method of Manufacturing Thin-Film Transistor Substrate]

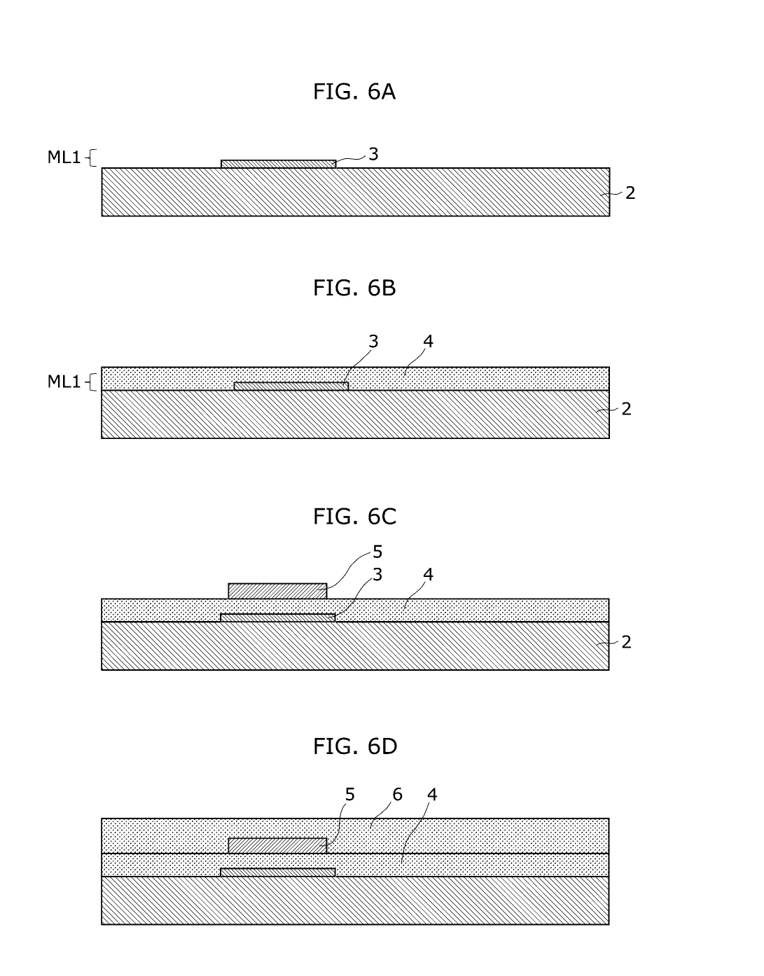

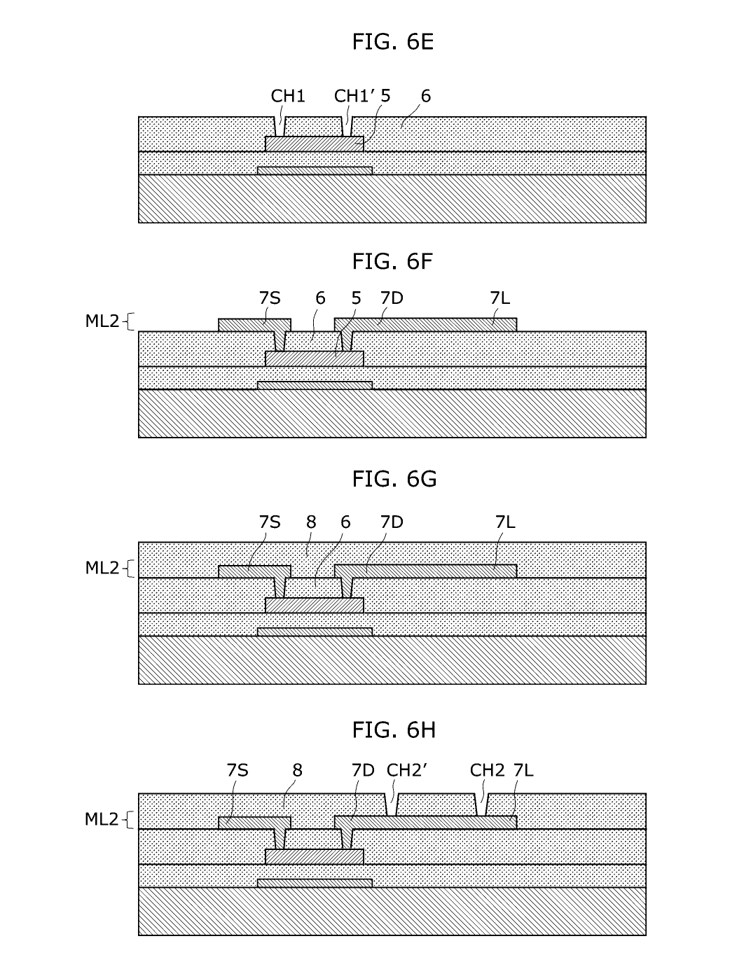

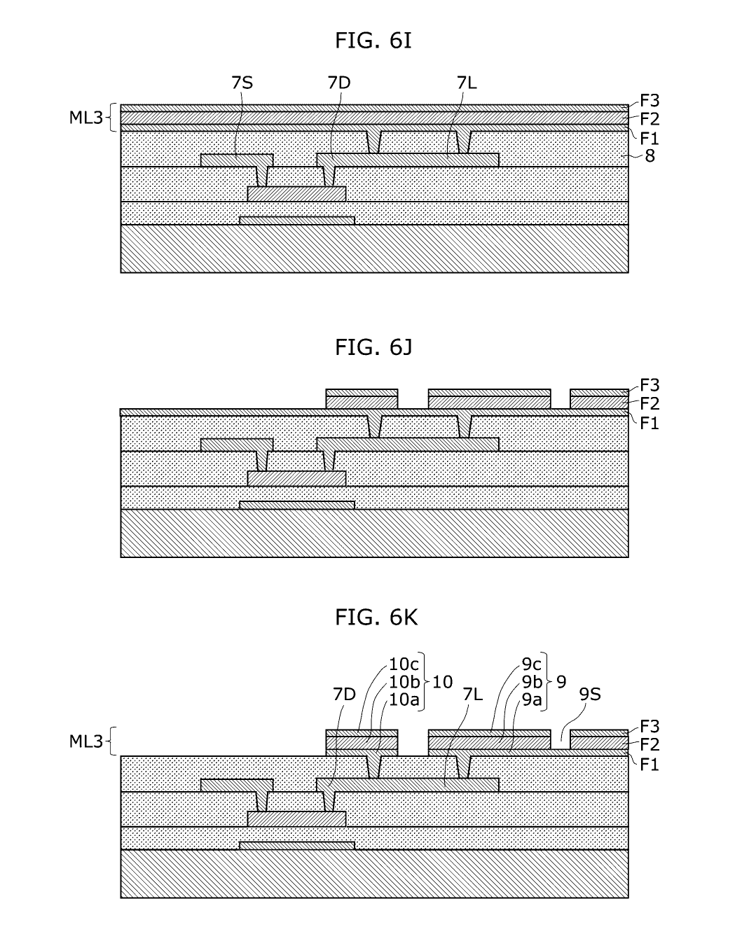

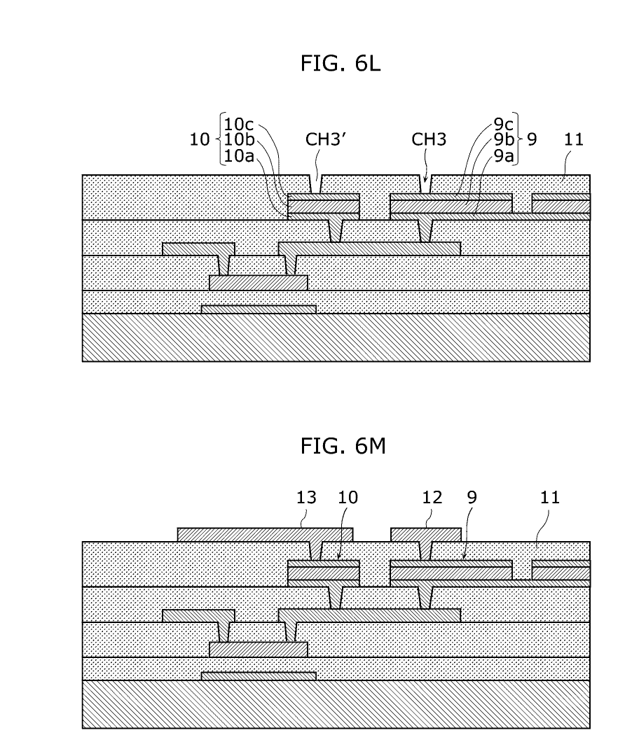

Next, a method of manufacturing the TFT substrate 1 according to Embodiment is described, with reference to FIG. 6A to FIG. 6M. Each of FIG. 6A to FIG. 6M is a cross-sectional view showing a process in the method of manufacturing the TFT substrate according to Embodiment.

First, the substrate 2 is prepared, and the gate electrode 3 is formed in the predetermined shape above the substrate 2 as shown in FIG. 6A. The gate electrode 3 is formed in the predetermined shape by, for example, forming a gate metal film on the substrate 2 by the sputtering method and subsequently processing this gate metal film by a photolithography method and a wet etching method.

It should be noted that when patterning is performed on the gate metal film, an electrode, a line, and the like other than the gate electrode 3 may be formed as the electrode and the line of the first metal layer ML1, as needed.

Next, the gate insulating film 4 is formed above the substrate 2, as shown in FIG. 6B. As an example, the gate insulating film 4, which comprises a silicon oxide, is formed by, for instance, the plasma CVD method in a manner that the gate electrode 3 is covered.

Here, note that the line, the electrode, and the like other than the gate electrode 3 are covered by the gate insulating film 4 as well.

Next, the oxide semiconductor layer 5 is formed in the predetermined shape above the substrate 2 as shown in FIG. 6C. In Embodiment, the oxide semiconductor layer 5 is formed on the gate insulating film 4.

The oxide semiconductor layer 5 is formed in the predetermined shape above the gate electrode 3 by, for example, forming a transparent amorphous oxide semiconductor comprising InGaZnOx on the gate insulating film 4 by the sputtering method and subsequently processing this transparent amorphous oxide semiconductor by the photolithography method and an etching method.

Following this, the insulating layer 6 is formed on the gate insulating film 4 in manner that the oxide semiconductor layer 5 is covered, as shown in FIG. 6D. As an example, the insulating layer 6 comprising a silicon oxide film is formed by the plasma CVD.

Next, the contact holes enabling the oxide semiconductor layer 5 to contact the source electrode 7S and the drain electrode 7D are formed by partially etching the insulating layer 6, as shown in FIG. 6E. For example, contact holes CH1 and CH1′ are formed in the insulating layer 6 to partially expose the oxide semiconductor layer 5, by the photolithography method and the etching method.

Following this, the source electrode 7S and the drain electrode 7D are formed in the predetermined shapes as the electrodes connected to the oxide semiconductor layer 5, as shown in FIG. 6F.

To be more specific, a Cu film is formed on the insulating layer 6 by the sputtering method in a manner that the contact holes CH1 and CH1′ of the insulating layer 6 are filled. Then, the Cu film is processed by the photolithography method and the etching method to form the source electrode 7S and the drain electrode 7D in the predetermined shapes. Here, note that the extension line 7L is formed as well.

It should be noted that when patterning is performed on Cu, an electrode, a line, and the like other than the source electrode 7S and the drain electrode 7D, and the extension line 7L may be formed as the electrode and the line of the second metal layer ML2, as needed.

Next, the insulating layer 8 is formed on the insulating layer 6 in a manner that the source electrode 7S, the drain electrode 7D, and the extension line 7L are covered, as shown in FIG. 6G. For example, the insulating layer 8, which comprises a silicon oxide film, is formed by the plasma CVD at a film deposition temperature of 300° C.

Here, note that the line, the electrode, and the like other than the source electrode 7S, the drain electrode 7D, and the extension line 7L are covered by the insulating layer 8 as well.

Next, the contact holes are formed by partially etching the insulating layer 8 in a manner that the source electrode 7S or the drain electrode 7D is exposed. In Embodiment, two contact holes CH2 and CH2′ are formed in the insulating layer 8 by the photolithography method and the etching method in a manner that the drain electrode 7D and the extension line 7L are partially exposed.

It should be noted that the contact holes may be formed in the insulating layer 8 in a manner that the line, the electrode, and the like other than the source electrode 7S, the drain electrode 7D, and the extension line 7L are exposed, as needed.

Next, the first wiring line 9 connected to at least one of the source electrode 7S and the drain electrode 7D is formed in a procedure as shown in FIGS. 6I to 6K. In Embodiment, the first wiring line 9 is formed to be connected to the drain electrode 7D that is exposed. Moreover, in Embodiment, the second wiring line 10 spaced from the first wiring line 9 is also formed to be connected to the drain electrode 7D.

As shown in FIG. 6I, the procedure for forming the first wiring line 9 and the second wiring line 10 includes the following: a process of forming a first film F1, which is a transparent conductive film; a process of forming a second film F2, which is a copper film, on the first film F1 (the transparent conductive film); and a process of forming a third film F3, which is a CuMn alloy film, on the second film F2 (the Cu film).

After the first film F1 (the transparent conductive film), the second film F2 (the Cu film), and the third film F3 (the CuMn alloy film) are formed, the procedure for forming the first wiring line 9 and the second wiring line 10 further includes the following: a process of patterning the third film F3 and the second film F2 by the etching method as shown in FIG. 6J (a first patterning process); and subsequently, a process of patterning the first film F1 by the etching method as shown in FIG. 6K (a second patterning process).

To be more specific, the first wiring line 9 and the second wiring line 10 are formed as follows.

First, the first film F1, which is the transparent conductive film, is formed on the insulating layer 8 in a manner that the contact holes CH2 and CH2′ of the insulating layer 8 are filled, as shown in FIG. 6I. In Embodiment, an ITO film is formed as the first film F1 (the transparent conductive film) by the sputtering method. Following this, the second film F2, which is the Cu film, is formed on the first film (the transparent conductive film) by the sputtering method. Then, the third film F3, which is the CuMn alloy film, is formed on the second film F2 (the Cu film) by the sputtering method.

After this, the third film F3 and the second film F2 are processed into predetermined shapes by the photolithography method and the etching method (the first patterning process), as shown in FIG. 6J. In Embodiment, patterning is performed on the third film F3, which is the CuMn alloy film, and the second film F2, which is the Cu film, by the wet etching method using a hydrogen peroxide solution as an etchant.

Next, the first film F1 is processed into a predetermined shape by the photolithography method and the etching method (the second patterning process), as shown in FIG. 6K. In Embodiment, patterning is performed on the first film F1, which is the ITO film, in a manner that the first film F1 has the same shape as the third film F3 and the second film F2 in a planar view, by the wet etching method using an oxalic-acid based etchant. However, the first film F1 (the ITO film) in the slit part 9S remains without being etched.

In this way, the first wiring line 9 and the second wiring line 10 are formed in the predetermined shapes, as shown in FIG. 6I to FIG. 6K. The first wiring line 9 comprises a multilayer film including the first film 9a, the second film 9b, and the third film 9c. The second wiring line 10 comprises a multilayer film including the first film 10a, the second film 10b, and the third film 10c.

In Embodiment, the first wiring line 9 and the second wiring line 10 are patterned into the predetermined shapes by etching performed twice after the first film F1, the second film F2, and the third film F3 are laminated. However, the formation of the first wiring line 9 and the second wiring line 10 is not limited to this. For example, the first wiring line 9 and the second wiring line 10 may be patterned into the predetermined shapes by forming and etching the second film F2 and the third film F3 after forming and etching the first film F1.

More specifically, the first film F1 is first formed on the insulating layer 8 and then patterned into the predetermined shape by the photolithography method and the wet etching method. In this case, an oxalic-acid based etchant may be used.

Next, the second film F2 and the third film F3 are formed on the first film F1 patterned in the predetermined shape, and then patterned into the predetermined shapes by the photolithography method and the wet etching method. In this case, a hydrogen-peroxide based etchant may be used.

In this way, the first wiring line 9 and the second wiring line 10 can be formed in the predetermined shapes as shown in FIG. 6K.

Next, the insulating layer 11 is formed on the insulating layer 8 in a manner that the first wiring line 9 and the second wiring line 10 are covered. Following this, contact holes CH3 and CH3′ are formed in the insulating layer 11 in a manner that the first wiring line 9 and the second wiring line 10 are exposed as shown in FIG. 6L.

For example, a photosensitive coating material comprising an acrylic resin is applied in a manner that the first wiring line 9 and the second wiring line 10 are covered. Then, the insulating layer 11 having the contact holes CH3 and CH3′ is formed by exposing and developing this photosensitive coating material. As a result of this, the third film 9c of the first wiring line 9 and the third film 10c of the second wiring line 10 are exposed.

Next, the terminal 12 in the predetermined shape to be connected to the first wiring line 9 and the electrode 13 in the predetermined shape to be connected to the second wiring line 10 are formed, as shown in FIG. 6M. To be more specific, an Al alloy film is first formed on the insulating layer 11 by the sputtering method in a manner that the contact holes CH3 and CH3′ of the insulating layer 11 are filled. Following this, the terminal 12 and the electrode 13 are formed in the predetermined shapes by processing the Al alloy film by the photolithography method and the etching method. The Al alloy film may be patterned by the wet etching method using, for example, a PAN-based etchant.

### [Function Effect etc.]

The following describes a function effect of the TFT substrate 1 according to Embodiment as well as a background to the technology according to the present disclosure.

In recent years, wiring lines formed on TFT substrates tend to be longer and thinner because of display apparatuses with larger screens or higher resolutions. This results in an increase in the wiring resistance and thereby decreases the quality of displayed images. Thus, a lower wiring resistance is desired.

A source electrode and a drain electrode of a thin-film transistor are partially extended to function as a line in some cases. Moreover, a wiring line formed in the same layer as the source electrode and the drain electrode is formed by patterning a conductive film formed using the same material as the material used for the source electrode and the drain electrode. On account of this, the source electrode and the drain electrode are required to perform not only as the TFTs but also as the wiring lines.

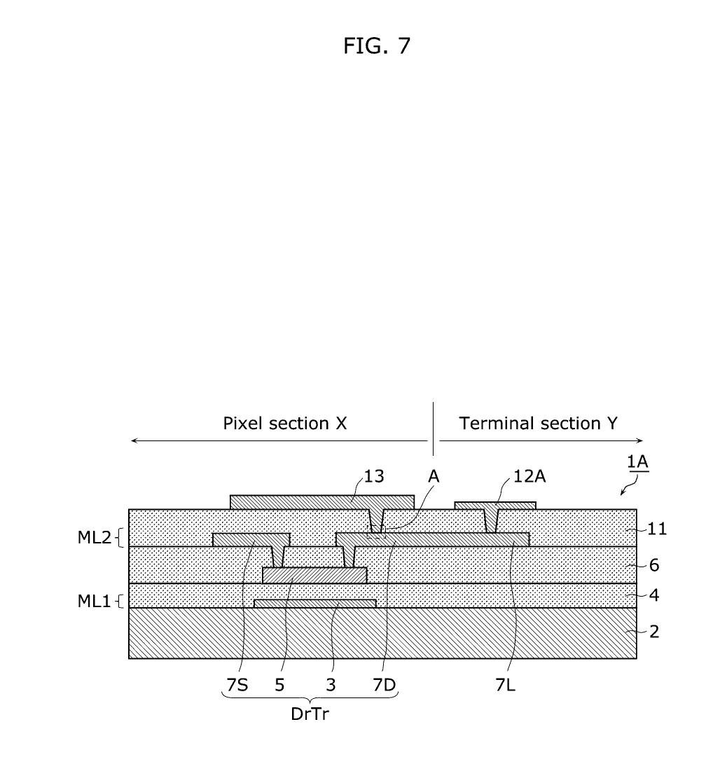

With this being the situation, it has been proposed that copper (Cu), which is a low-resistance material, is used as the material for the source electrode and the drain electrode. As an example, a TFT substrate 1A shown in FIG. 7 is proposed.

FIG. 7 is a diagram showing the TFT substrate 1A including a thin-film transistor DrTr having a source electrode 7S and a drain electrode 7D made using Cu as a material. More specifically, each of the source electrode 7S and the drain electrode 7D is a Cu film.

Furthermore, the TFT substrate 1A includes an electrode (an anode) 13 and a terminal 12A formed on an insulating layer (a flattening layer) 11. The electrode 13 and the terminal 12A are connected to the drain electrode 7D and an extension line 7L, respectively, via contact holes formed in the insulating layer 11. The terminal 12A is a drain terminal (an extraction electrode) formed in a terminal section Y, and is an ITO film.

However, the TFT substrate 1A shown in FIG. 7 has the following problems.

Firstly, the TFT substrate 1A shown in FIG. 7 increases in the wiring resistance because of a two-layer wiring structure that includes: a first metal layer ML1 in which a gate electrode 3 is formed; and a second metal layer ML2 in which the source electrode 7S and the drain electrode 7D are formed. Furthermore, since the lines can be routed through only two layers, a degree of freedom in designing the wiring layout is low and thus it is difficult to achieve multiple wiring of, for example, 8W.

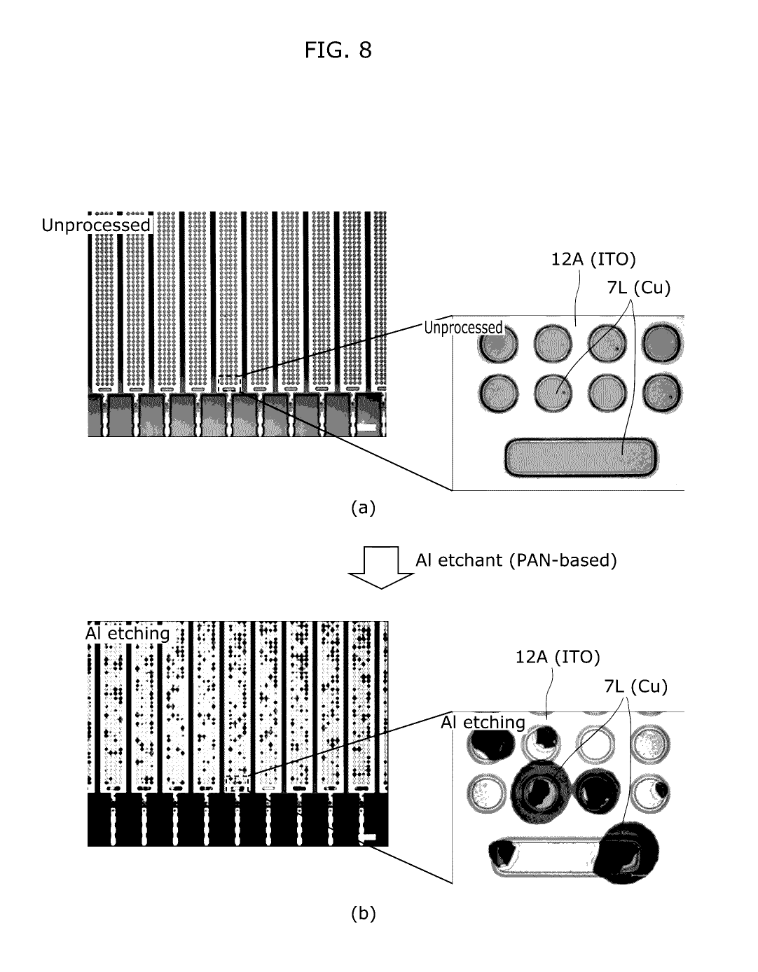

Secondly, a defect occurs to the terminal section Y when the electrode 13 (the Al alloy film) is etched, as shown in FIG. 8. FIG. 8 is a plan view showing that the terminal section Y of the TFT substrate 1A shown in FIG. 7 is etched.

More specifically, pinholes occur to the terminal 12A, which is the ITO film. On this account, when the electrode 13, which is the Al alloy film, is patterned by the wet etching method using a PAN-based Al etchant, the Al etchant enters via the pinholes of the ITO film to melt the extension line 7L (the drain line), which is the Cu film directly under the terminal 12A, as shown in (a) and (b) of FIG. 8.

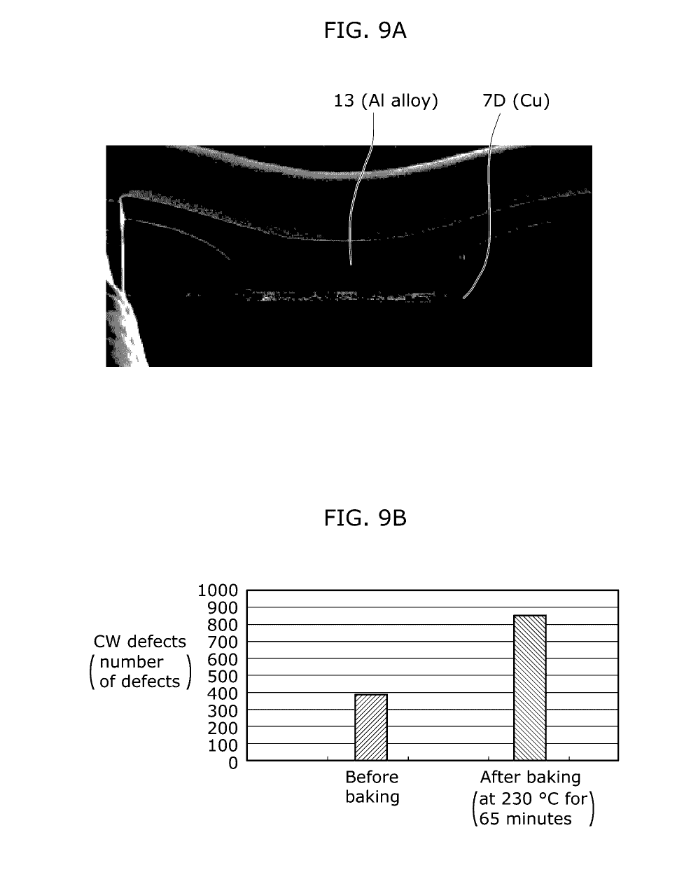

Thirdly, contact between the electrode 13 (the Al alloy film) and the drain electrode 7D (the Cu film) is poor because of mutual diffusion of Al alloy and Cu, as shown in FIG. 9A. This is believed to result from the quality deterioration of the Cu film because the Al atoms of the Al alloy absorb the Cu atoms of the Cu film. FIG. 9A is a cross-sectional SEM image of a region A enclosed by a broken line shown in FIG. 7.

The actual counted number of poor contacts as contact window defects (CW defects) was about 400 per lot before baking, as shown in FIG. 9B. Furthermore, after baking at 230° C. for 65 minutes, about 850 CW defects per lot occurred. Such a poor contact between the electrode 13 and the drain electrode 7D results in unlit defects of the pixels of the organic EL display apparatus.

The technology according to the present disclosure is based on such underlying knowledge. As shown in FIG. 4, the TFT substrate 1 including the thin-film transistor DrTr having the source electrode 7S and the drain electrode 7D made using Cu as a material includes the following: the first wiring line 9 that is formed in a layer positionally higher than a layer in which the source electrode 7S and the drain EL 7D are formed, and is connected to the drain electrode 7D; and the terminal 12 that comprises an Al alloy, is formed in a layer positionally higher than the layer in which the first wiring line 9 is formed, and is connected to the first wiring line 9. Note that the first wiring line 9 is formed as a multilayer film including the first film 9a that is a transparent conductive film (ITO film), the second film 9b that is a Cu film, and the third film 9c that is a CuMn alloy film.

Thus, the TFT substrate 1 has a three-layer wiring structure that includes: the first metal layer ML1 in which the gate electrode 3 is formed; the second metal layer ML2 in which the source electrode 7S and the drain electrode 7D are formed; and the third metal layer ML3 in which the first wiring line 9 (the upper line) is formed. This three-layer wiring of the TFT substrate 1 can reduce the wiring resistance. Moreover, the degree of freedom in designing the wiring layout can be increased.

Furthermore, the terminal structure of the terminal section Y of the TFT substrate 1 includes the extension line 7L, the first wiring line 9, and the terminal 12 (that is, Al-alloy/CuMn/Cu/ITO/Cu). With this structure, even when a pinhole occurs to the transparent conductive film 9a (the ITO film), the extension line 7L (the drain line), which is the Cu film, can be prevented from being melted by the etchant used for patterning the electrode 13. In other words, the CuMn film formed above the ITO film functions as a barrier film preventing the entry of the etchant.

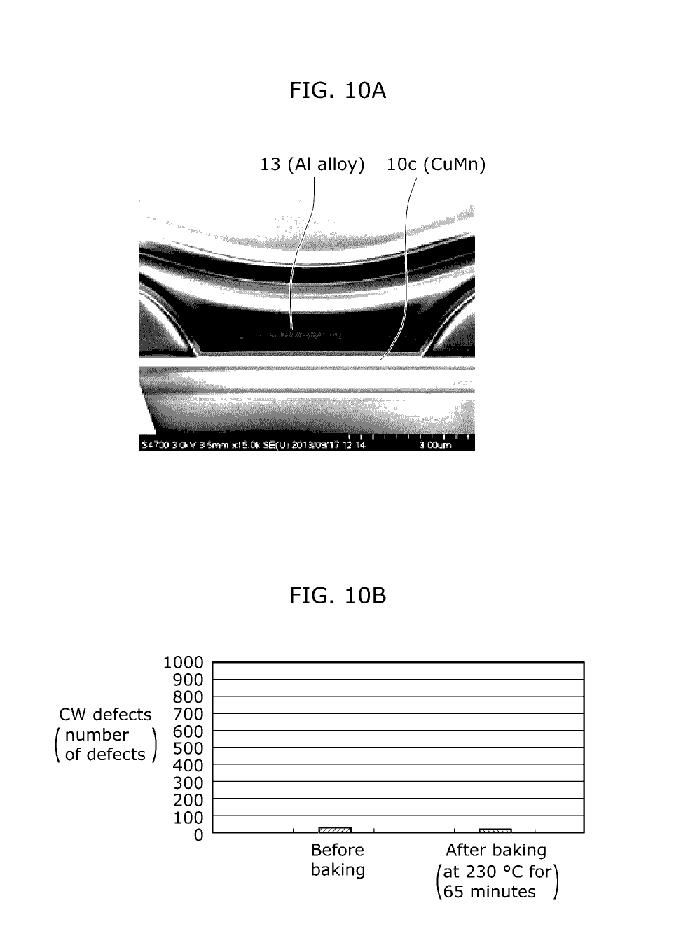

Moreover, the TFT substrate 1 includes the third film 10c (the CuMn alloy film) interposed between the electrode 13 (the Al alloy film) and the drain electrode 7D (the Cu film) or the second film 10b (the Cu film). More specifically, the CuMn film is interposed between the Al alloy film and the Cu film. This can reduce the mutual diffusion of Al alloy and Cu caused by the contact between Al alloy and Cu. This, in turn, can reduce the occurrence of the poor contact, as shown in FIG. 10A. FIG. 10A is a cross-sectional SEM image of a region A enclosed by a broken line in FIG. 4.

The actual counted number of poor contacts as CW defects was about a few tens per lot both before and after baking, as shown in FIG. 10B. Therefore, the unlit defects of the organic EL display apparatus can be reduced.

In Embodiment, the third film 9c (the CuMn alloy film) is also interposed between the terminal 12 (the Al alloy film) and the extension line 7L (the Cu film) or the second film 9b (the Cu film). This thus can reduce the occurrence of poor contact of the terminal 12.

As described thus far, the TFT substrate 1 according to Embodiment can achieve a TFT substrate having desired performance even when Cu is used as the material for the source electrode 7S and the drain electrode 7D.

### (Modifications etc.)

The thin-film transistor substrate, the method of manufacturing the thin-film transistor substrate, and the organic EL display apparatus according to Embodiment have been described thus far. However, the present disclosure is not limited to Embodiment described above.

For example, although the thin-film transistor according to Embodiment is a bottom-gate TFT, the thin-film transistor may be a top-gate TFT.

Moreover, although the thin-film transistor according to Embodiment is a channel-etching stopper (channel-protection) TFT, the thin-film transistor may be a channel-etching TFT. In other words, the insulating layer 6 according to Embodiment may not be formed.

Furthermore, Embodiment above describes the organic EL display apparatus as a display apparatus including the thin-film transistor substrate. However, the thin-film transistor substrate can also be applied to other display apparatuses, such as liquid crystal display apparatuses, which include active matrix substrates.

Moreover, the display apparatus (the display panel) such as the organic EL display apparatus described above is also applicable to various kinds of electronic equipment having display panels, such as television sets, personal computers, or cellular phones. The display apparatus is particularly suitable for large-screen or high-resolution display apparatuses.

Other embodiments implemented through various changes and modifications conceived by a person of ordinary skill in the art or through a combination of the structural elements in different embodiments and modifications described above may be included in the scope in an aspect or aspects according to the present invention, unless such changes, modifications, and combination depart from the scope of the present invention.

### INDUSTRIAL APPLICABILITY

A technology disclosed here can be widely used for thin-film transistor substrates including oxide semiconductors, methods of manufacturing such thin-film transistor substrates, and display apparatuses such as organic EL display apparatuses including such thin-film transistor substrates.

[Reference Signs List]

| | |
|---|---|
| 1, 1A | TFT substrate |
| 2 | Substrate |
| 3, G1, G2 | Gate electrode |
| 4 | Gate insulating film |
| 5 | Oxide semiconductor layer |
| 6, 8, 11 | Insulating layer |
| 7S, S1, S2 | Source electrode |
| 7D, D1, D2 | Drain electrode |
| 7L | Extension line |
| 9 | First wiring line |
| 9a, 10a, F1 | First film |
| 9b, 10b, F2 | Second film |
| 9c, 10c, F3 | Third film |
| 9S | Slit part |
| 10 | Second wiring line |
| 12, 12A | Terminal |
| 13 | Electrode |
| 100 | Organic EL display apparatus |
| 110 | Pixel |
| 110R, 110G, 110B | Subpixel |
| 111 | Bank |
| 120 | Pixel circuit |
| 130 | Organic EL element |
| 131 | Anode |
| 132 | EL layer |
| 133 | Cathode |
| 140 | Gate line |
| 150 | Source line |
| 160 | Power source line |
| SwTr, DrTr | Thin-film transistor |
| C | Capacitor |
| ML1 | First metal layer |
| ML2 | Second metal layer |
| ML3 | Third metal layer |
| Ch1, CH1′, CH2, CH2′, CH3, CH3′ | Contact hole |

1. A thin-film transistor substrate that has a thin-film transistor including an oxide semiconductor layer, a source electrode, and a drain electrode, the thin-film transistor substrate comprising:
a first wiring line that is formed in a layer positionally higher than a layer in which the source electrode and the drain electrode are formed, and is connected to at least one of the source electrode and the drain electrode; and
a terminal that is formed in a layer positionally higher than the layer in which the first wiring line is formed, and is connected to the first wiring line,
wherein the at least one of the source electrode and the drain electrode that is connected to the first wiring line contains copper,
the first wiring line is a multilayer film in which a transparent conductive film, a copper film, and a copper-manganese alloy film are laminated in stated order from the bottom, and
the terminal comprises an aluminum alloy.

2. The thin-film transistor substrate according to claim 1, further comprising
an electrode that is formed in the layer in which the terminal is formed,
wherein the electrode and the terminal comprise a same material.

3. The thin-film transistor substrate according to claim 2,
wherein the electrode is an anode of an organic electroluminescent (EL) element.

4. The thin-film transistor substrate according to claim 2, comprising
a second wiring line that is formed in the layer in which the first wiring line is formed, and is connected to the electrode,
wherein the second wiring line is a multilayer film having a same structure as the first wiring line.

5. The thin-film transistor substrate according to claim 1,
wherein the transparent conductive film is an indium tin oxide film.

6. The thin-film transistor substrate according to claim 1,
wherein the thin-film transistor has a gate electrode,
the gate electrode is formed in a first layer,
the source electrode and the drain electrode are formed in a second layer positionally higher than the first layer, and
the first wiring line is formed in a third layer positionally higher than the second layer.

7. The thin-film transistor substrate according to claim 1,
wherein the first wiring line has a slit part in which the copper film and the copper-manganese alloy film are cut.

8. The thin-film transistor substrate according to claim 1,
wherein the oxide semiconductor layer is a transparent amorphous oxide semiconductor.

9. An organic EL display apparatus comprising:
the thin-film transistor substrate according to claim 1; and
an organic EL element formed on the thin-film transistor substrate.

10. A method of manufacturing a thin-film transistor substrate, the method comprising:
forming an oxide semiconductor layer;
forming a source electrode and a drain electrode that are connected to the oxide semiconductor layer;
forming a first wiring line in a layer positionally higher than a layer in which the source electrode and the drain electrode are formed, the first wiring line being connected to at least one of the source electrode and the drain electrode; and
forming a terminal in a layer positionally higher than the layer in which the first wiring line is formed, the terminal being connected to the first wiring line,
wherein the at least one of the source electrode and the drain electrode that is connected to the first wiring line contains copper,
the terminal comprises an aluminum alloy, and
the forming of a first wiring line includes forming a transparent conductive film, forming a copper film on the transparent conductive film, and forming a copper-manganese alloy film on the copper film.

11. The method of manufacturing a thin-film transistor substrate according to claim 10,
wherein the forming of a first wiring line further includes, after the transparent conductive film, the copper film, and the copper-manganese alloy film are formed: patterning the copper-manganese alloy film and the copper film by etching; and subsequently patterning the transparent conductive film by etching.
